(19) United States
(12) Patent Application Publication
(10) Pub. No.: US 2026/0299347 A1
(43) Pub. Date: Oct. 1, 2026

(54) DISPLAY APPARATUS

(71) Applicant: AUO Corporation, Hsinchu City (TW)

(72) Inventors: Ti-Kuei Yu, Hsinchu City (TW); Ting Hsieh, Hsinchu City (TW); Yueh-Chi Wu, Hsinchu City (TW)

(73) Assignee: AUO Corporation, Hsinchu City (TW)

(21) Appl. No.: 19/332,092

(22) Filed: Sep. 18, 2025

(30) Foreign Application Priority Data
Mar. 26, 2025 (TW) 114111393

(51) Int. Cl. G02F 1/1333; G02F 1/13357; G02F 1/1339; H10H 29/855

(52) U.S. Cl. CPC G02F 1/133388; G02F 1/133305; G02F 1/1336; G02F 1/1339; H10H 29/8552

(57) ABSTRACT

A display apparatus of the disclosure is provided with a first planar display area and a bendable display area. The display apparatus includes a first substrate, a second substrate, a first display medium layer, a first flexible substrate, a second flexible substrate, and a plurality of first light-emitting elements. The first substrate and the second substrate are disposed in the first planar display area and opposite to each other. The first display medium layer is disposed between the first substrate and the second substrate and located in the first planar display area. The first flexible substrate and the second flexible substrate are disposed in the bendable display area and opposite to each other. The plurality of first light-emitting elements are disposed between the first flexible substrate and the second flexible substrate and located in the bendable display area.

### CROSS-REFERENCE TO RELATED APPLICATION

This application claims the priority benefit of Taiwan application serial no. 114111393, filed on Mar. 26, 2025. The entirety of the above-mentioned patent application is hereby incorporated by reference herein and made a part of this specification.

### BACKGROUND

### Technical Field

The disclosure relates to a display apparatus, and more particularly to a bendable display apparatus.

### Description of Related Art

Bendable splicing display apparatuses with high flexibility for different usage scenarios have gradually gained market favor. Among them, one existing type of bendable splicing display apparatus utilizes liquid crystal display panels for splicing display images. In order to enable such splicing display apparatuses to be bendable, two liquid crystal display panels are connected by a bendable mechanism. However, this results in a discontinuity in the display image, thereby affecting viewing quality.

### SUMMARY

The disclosure provides a bendable display apparatus having improved integrity in splicing display.

A display apparatus of the disclosure is provided with a first planar display area and a bendable display area. The display apparatus includes a first substrate, a second substrate, a first display medium layer, a first flexible substrate, a second flexible substrate, and a plurality of first light-emitting elements. The first substrate and the second substrate are disposed in the first planar display area and opposite to each other. The first display medium layer is disposed between the first substrate and the second substrate and located in the first planar display area. The first flexible substrate and the second flexible substrate are disposed in the bendable display area and opposite to each other. The plurality of first light-emitting elements are disposed between the first flexible substrate and the second flexible substrate and located in the bendable display area.

Based on the above, in a display apparatus according to an embodiment of the disclosure, a plurality of light-emitting elements are adapted to perform display in the bendable display area to improve image continuity between the planar display area and the bendable display area. In addition, since these light-emitting elements are disposed between two flexible substrates, protection for the light-emitting elements can be significantly enhanced.

### BRIEF DESCRIPTION OF THE DRAWINGS

FIG. 1 is a schematic view of a display apparatus according to a first embodiment of the disclosure when bent.

FIG. 2 is a schematic view of the display apparatus of FIG. 1 when folded.

FIG. 3 is a partially enlarged schematic cross-sectional view of the display apparatus of FIG. 1.

FIG. 4 is a schematic cross-sectional view of a display apparatus according to a second embodiment of the disclosure.

FIGS. 5A to 5C are schematic cross-sectional views illustrating a manufacturing process of the display apparatus of FIG. 4.

FIG. 6 is a schematic cross-sectional view of a display apparatus according to a third embodiment of the disclosure.

FIG. 7A is a schematic top view of a light-shielding layer of FIG. 6.

FIG. 7B is a schematic top view of another embodiment of the light-shielding layer of FIG. 6.

### DESCRIPTION OF THE EMBODIMENTS

As used herein, the terms “approximately,” “about,” “substantially,” or “essentially” include the stated values as well as average values within an acceptable deviation range as would be determined by a person skilled in the art, taking into account specific quantities of measurement and the errors associated with measurement (i.e., limitations of the measurement system). For example, “about” may refer to within one or more standard deviations from the stated value, or within ±30%, ±20%, ±15%, ±10%, or ±5%. Furthermore, depending on the nature of the measurement, cutting process, or other relevant properties, the terms “approximately,” “about,” “substantially,” or “essentially” may be interpreted with a selectively acceptable deviation range or standard deviation, and a single standard deviation does not necessarily apply to all properties.

In the drawings, for clarity, the thicknesses of layers, films, panels, and regions are exaggerated. It should be understood that when components such as layers, films, regions, or substrates are described as being “on” or “connected to” another component, they may be directly on or connected to the other component, or intermediate components may also be present. Conversely, when components are described as being “directly on” or “directly connected to” another component, no intermediate components are present. As used herein, “connected” may refer to physical and/or electrical connection. Additionally, “electrically connected” may still allow for other components to exist between the two elements.

Moreover, relative terms such as “lower” or “bottom” and “upper” or “top” may be used herein to describe the relationship between components as shown in the FIG.s. It should be understood that such relative terms are intended to encompass different orientations of the device beyond those shown in the drawings. For example, if a device in a drawing is flipped, the component described as being “below” another component may now be positioned “above” it. Thus, exemplary terms such as “lower” may include both “lower” and “upper” orientations, depending on the specific orientation in the FIG.s. Similarly, a component described as being “under” or “beneath” another may also be situated “over” or “above” it if the FIG. is flipped. Therefore, exemplary terms like “above” or “below” may include both orientations.

The exemplary embodiments described herein are referenced to schematic cross-sectional views, which are idealized examples. Variations in the illustrated shapes due to, for example, manufacturing techniques and/or tolerances are to be expected. Therefore, the embodiments described herein should not be construed as limited to the specific shapes illustrated, but rather include shape deviations that result from manufacturing. For instance, regions shown or described as flat may exhibit rough and/or nonlinear characteristics. Additionally, sharp corners shown in the drawings may in reality be rounded. As such, the regions illustrated in the FIG. s are essentially schematic and are not intended to depict exact shapes, nor to limit the scope of the claimed disclosure.

Detailed reference will now be made to exemplary embodiments of the present disclosure, examples of which are illustrated in the accompanying drawings. Wherever possible, the same reference numerals are used throughout the drawings and description to refer to the same or like parts.

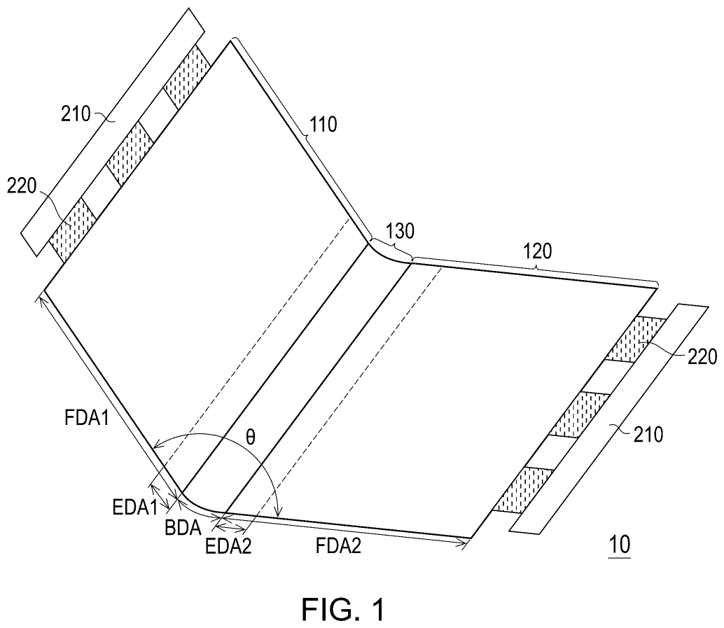

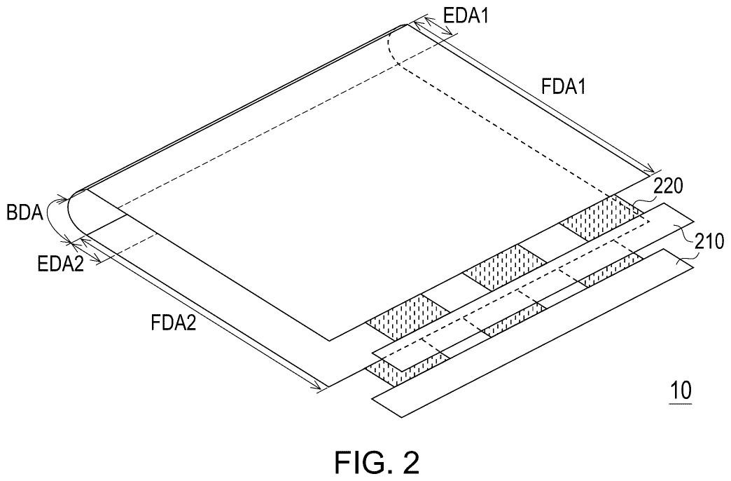

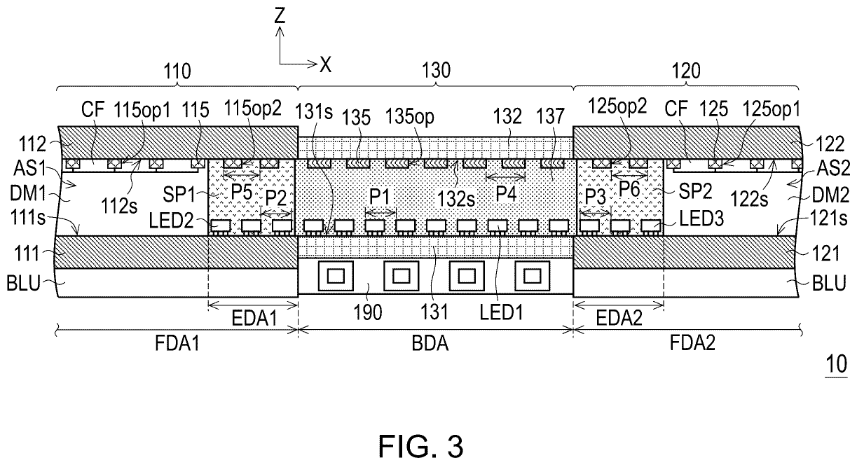

FIG. 1 is a schematic view of a display apparatus according to a first embodiment of the disclosure when bent. FIG. 2 is a schematic view of the display apparatus of FIG. 1 when folded. FIG. 3 is a partially enlarged schematic cross-sectional view of the display apparatus of FIG. 1. Referring to FIGS. 1 and 2, in the embodiment, a display apparatus 10 may include a first display panel 110, a second display panel 120, and a bendable display panel 130, wherein the bendable display panel 130 is used to splice the first display panel 110 and the second display panel 120.

The first display panel 110 and the second display panel 120 are both planar displays, and respectively define a first planar display area FDA1 and a second planar display area FDA2 of the display apparatus 10. For example, the first display panel 110 and the second display panel 120 may each be electrically connected to a driving circuit board 210 through a plurality of flexible circuit board 220, but the disclosure is not limited thereto. The driving circuit board 210 is configured to provide driving signals for the first display panel 110, the second display panel 120, and the bendable display panel 130.

The bendable display panel 130 defines a bendable display area BDA of the display apparatus 10. It is first noted that the bendable display area BDA is connected between the first planar display area FDA1 and the second planar display area FDA2, and is configured to improve the image consistency between the first display panel 110 and the second display panel 120 when splicing displays. In addition, through the connection of the bendable display panel 130, the display apparatus 10 allows the angle θ (as shown in FIG. 1) between the first display panel 110 and the second display panel 120 to be adjusted arbitrarily during operation to achieve the desired splicing display effect, or to fold the display apparatus 10 to enhance portability (as shown in FIG. 2).

Referring to FIGS. 1 and 3, in the embodiment, the first display panel 110 may include a substrate 111, a substrate 112, and a display medium layer DM1. The substrate 111 and the substrate 112 are disposed in the first planar display area FDA1 and opposite to each other. The display medium layer DM1 is disposed between the substrate 111 and the substrate 112 and located in the first planar display area FDA1. Similarly, the second display panel 120 may include a substrate 121, a substrate 122, and a display medium layer DM2. The substrate 121 and the substrate 122 are disposed in the second planar display area FDA2 and opposite to each other. The display medium layer DM2 is disposed between the substrate 121 and the substrate 122. In the embodiment, the display medium layer DM1 and the display medium layer DM2 may be liquid crystal layers. That is, the first display panel 110 and the second display panel 120 may be, for example, liquid crystal display panels, but the disclosure is not limited thereto. The materials of the substrate 111 and the substrate 112 may include, for example, glass, quartz, or other rigid plates with high light transmittance.

For example, each of the substrate 111 and the substrate 121 may be provided with plurality of pixel structures (not shown) and a plurality of signal lines (not shown), wherein each pixel structure may include an active element (not shown) electrically connected to a pixel electrode (not shown). The plurality of signal lines may include, for example, a plurality of scan lines and a plurality of data lines, and each active element is electrically connected to at least one scan line and at least one data line, but the disclosure is not limited thereto.

On the other hand, a light-shielding layer 115 and a color filter layer CF may be disposed on the substrate 112, wherein the light-shielding layer 115 has a plurality of openings 115op1 overlapping the display medium layer DM1, and a plurality of filter patterns of the color filter layer CF are respectively disposed in the openings 115op1 of the light-shielding layer 115. Similarly, a light-shielding layer 125 and a color filter layer CF may be disposed on the substrate 122, wherein the light-shielding layer 125 has a plurality of openings 125op1 overlapping the display medium layer DM2. A plurality of filter patterns of the color filter layer CF are respectively disposed in the openings 125op1 of the light-shielding layer 125, and the filter patterns may have various filter colors such as red, green, and blue, but the disclosure is not limited thereto.

It should be noted that the foregoing overlapping relationship is, for example, defined along a normal direction (e.g., direction Z) of a surface 111s of the substrate 111. Hereinafter, unless otherwise specified, the overlapping relationship between two components is defined in this manner, and the overlapping direction will not be repeated.

Furthermore, the first display panel 110 may further include a sealant pattern SP1 disposed between the substrate 111 and the substrate 112. The second display panel 120 may further include a sealant pattern SP2 disposed between the substrate 121 and the substrate 122. More specifically, the sealant pattern SP1 is used to connect the substrate 111 and the substrate 112 and defines, together with the two substrates 111 and 112, an accommodation space AS1. The sealant pattern SP2 is used to connect the substrate 121 and the substrate 122 and defines, together with the two substrates 121 and 122, an accommodation space AS2. The display medium layer DM1 (e.g., liquid crystal layer) fills the accommodation space AS1, and the display medium layer DM2 (e.g., liquid crystal layer) fills the accommodation space AS2. The materials of the sealant pattern SP1 and the sealant pattern SP2 may include, for example, optical clear resin (OCR), optical clear adhesive (OCA), other transparent adhesives with high light transmittance, or the above materials doped with diffusion particles.

Since the first display panel 110 and the second display panel 120 of the embodiment are liquid crystal display panels, each is further provided with a backlight module BLU. The backlight module BLU can serve as an illumination light source when the first display panel 110 or the second display panel 120 is displaying. It should be noted that the disclosure is not limited to the driving mode of the liquid crystal layer of the liquid crystal display panel, such as twisted nematic (TN) mode, vertical alignment (VA) mode, electrically controlled birefringence (ECB) mode, in-plane switching (IPS) mode, or other suitable driving modes. Therefore, the electrode arrangement for driving the liquid crystal layer of the first display panel 110 and the second display panel 120 may be correspondingly designed according to the actual driving mode, and the disclosure is not limited thereto.

On the other hand, in the embodiment, the bendable display panel 130 includes a flexible substrate 131, a flexible substrate 132, and a plurality of light-emitting elements LED1. The flexible substrate 131 and the flexible substrate 132 are disposed in the bendable display area BDA and opposite to each other. The materials of the flexible substrate 131 and the flexible substrate 132 may include, for example, polyimide (PI), polyethylene terephthalate (PET), or other flexible plates with high light transmittance. The plurality of light-emitting elements LED1 are disposed between the flexible substrate 131 and the flexible substrate 132 and located in the bendable display area BDA. More specifically, the light-emitting elements LED1 may be electrically bonded to a surface 131s of the flexible substrate 131. For example, the plurality of light-emitting elements LED1 may have various light-emitting colors such as red, green, and blue, but the disclosure is not limited thereto.

For example, a plurality of pixel circuits (not shown) and a plurality of signal lines (not shown) may be disposed on the flexible substrate 131, wherein each pixel circuit may include at least one active element, at least one storage capacitor, and a driving electrode. The plurality of signal lines may include, for example, a plurality of scan lines, a plurality of data lines, and a plurality of power lines, and each pixel circuit may be electrically connected to a one scan line, one data line, and one power line. However, the disclosure is not limited thereto. On the other hand, a light-shielding layer 135 may be disposed on a surface 132s of the flexible substrate 132, wherein the light-shielding layer 135 has a plurality of openings 135op overlapping the plurality of light-emitting elements LED1.

Notably, the light-emitting elements LED1 disposed in the bendable display area BDA can significantly improve the image continuity among the first planar display area FDA1, the bendable display area BDA, and the second planar display area FDA2. On the other hand, by disposing the plurality of light-emitting elements LED1 between the flexible substrate 131 and the flexible substrate 132, protection for the light-emitting elements LED1 can be significantly enhanced.

To further improve image continuity between the first planar display area FDA1 and the bendable display area BDA, the first display panel 110 may further include a plurality of light-emitting elements LED2 disposed between the substrate 111 and the substrate 112. The light-emitting elements LED2 may be electrically bonded to the surface 111s of the substrate 111 and located in an edge display area EDA1 of the first planar display area FDA1 connected to the bendable display area BDA. For example, the plurality of light-emitting elements LED2 may have various light-emitting colors such as red, green, and blue, but the disclosure is not limited thereto.

Similarly, to further improve image continuity between the second planar display area FDA2 and the bendable display area BDA, the second display panel 120 may further include a plurality of light-emitting elements LED3 disposed between the substrate 121 and the substrate 122. The light-emitting elements LED3 may be electrically bonded to a surface 121s of the substrate 121 and located in an edge display area EDA2 of the second planar display area FDA2 connected to the bendable display area BDA. For example, the plurality of light-emitting elements LED3 may have various light-emitting colors such as red, green, and blue, but the disclosure is not limited thereto. In the embodiment, the light-emitting elements LED1, the light-emitting elements LED2, and the light-emitting elements LED3 may be, for example, micro light-emitting diodes (micro-LEDs) or mini light-emitting diodes (mini-LEDs), but the disclosure is not limited thereto.

In the embodiment, the plurality of light-emitting elements LED1 are arranged on the surface 131s of the flexible substrate 131 along a direction (e.g., direction X) parallel to the surface 131s of the flexible substrate 131 at intervals of a pitch P1. The plurality of light-emitting elements LED2 are arranged on the surface 111s of the substrate 111 along the direction at intervals of a pitch P2. The plurality of light-emitting elements LED3 are arranged on the surface 121s of the substrate 121 along the direction at intervals of a pitch P3. Preferably, the pitch P1, the pitch P2, and the pitch P3 may be equal to each other, but the disclosure is not limited thereto.

On the other hand, the light-shielding layer 115 disposed on the substrate 112 further has a plurality of openings 115op2 overlapping the plurality of light-emitting elements LED2, and the light-shielding layer 125 disposed on the substrate 122 further has a plurality of openings 125op2 overlapping the plurality of light-emitting elements LED3. To adjust the light output uniformity of the plurality of light-emitting elements LED1, LED2 and LED3 respectively in the edge display area EDA1 of the first display panel 110, the edge display area EDA2 of the second display panel 120, and the bendable display panel 130, an aperture ratio of the light-shielding layer 115 in the edge display area EDA1, an aperture ratio of the light-shielding layer 125 in the edge display area EDA2, and an aperture ratio of the light-shielding layer 135 in the bendable display area BDA may be different from each other.

For example, in the embodiment, the plurality of openings 135op of the light-shielding layer 135 are arranged on the surface 132s of the flexible substrate 132 along a direction (e.g., direction X) parallel to the surface 132s of the flexible substrate 132 at intervals of a pitch P4. The plurality of openings 115op2 of the light-shielding layer 115 are arranged on the surface 112s of the substrate 112 along the direction at intervals of a pitch P5. The plurality of openings 125op2 of the light-shielding layer 125 are arranged on the surface 122s of the substrate 122 along the direction at intervals of a pitch P6. In the embodiment, the pitch P4 may be different from the pitch P5 and the pitch P6, but the disclosure is not limited thereto.

In the embodiment, the bendable display panel 130 may further include an optical adhesive layer 137. The optical adhesive layer 137 is disposed between the flexible substrate 131 and the flexible substrate 132 and covers the plurality of light-emitting elements LED1 and the light-shielding layer 135. The materials of the optical adhesive layer 137 may include, for example, optical clear resin (OCR), optical clear adhesive (OCA), other transparent adhesives with high light transmittance, or the above materials doped with diffusion particles. Notably, the aforementioned sealant pattern SP1 is located in the edge display area EDA1 and covers the plurality of light-emitting elements LED2 and part of the light-shielding layer 115, and the aforementioned sealant pattern SP2 is located in the edge display area EDA2 and covers the plurality of light-emitting elements LED3 and part of the light-shielding layer 125.

It should be particularly noted that, in any direction (e.g., direction X) parallel to the surface 111s of the substrate 111, the surface 131s of the flexible substrate 131 may be aligned with the surface 111s of the substrate 111 and the surface 121s of the substrate 121. On the other hand, in any direction (e.g., direction X) parallel to the surface 112s of the substrate 112, the surface 132s of the flexible substrate 132 may be aligned with the surface 112s of the substrate 112 and the surface 122s of the substrate 122.

To enhance the support of the display apparatus 10 in the bendable display area BDA, the display apparatus 10 may further include a hinge structure 190 disposed in the bendable display area BDA and located on a side of the flexible substrate 131 facing away from the plurality of light-emitting elements LED1.

The following will enumerate other embodiments to describe the disclosure in detail. T same reference numerals will be used to indicate the same components, and the description of identical technical content will be omitted. For the omitted portions, please refer to the foregoing embodiments, and they will not be repeated hereinafter.

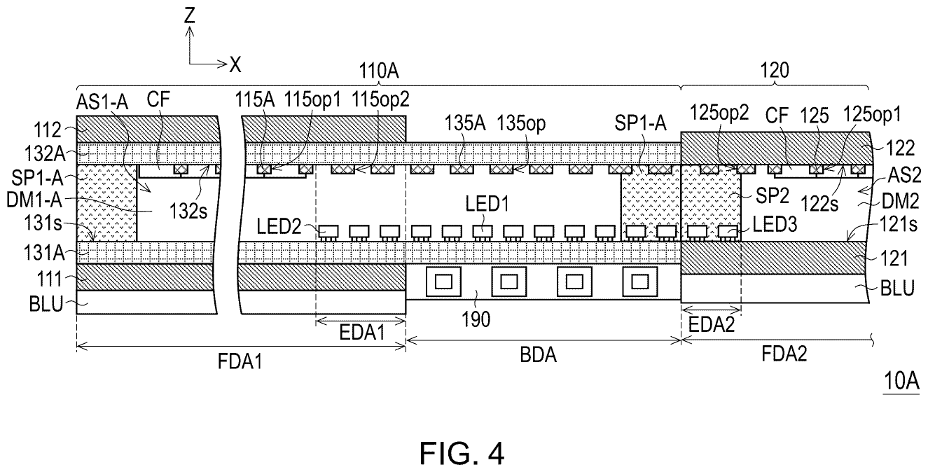

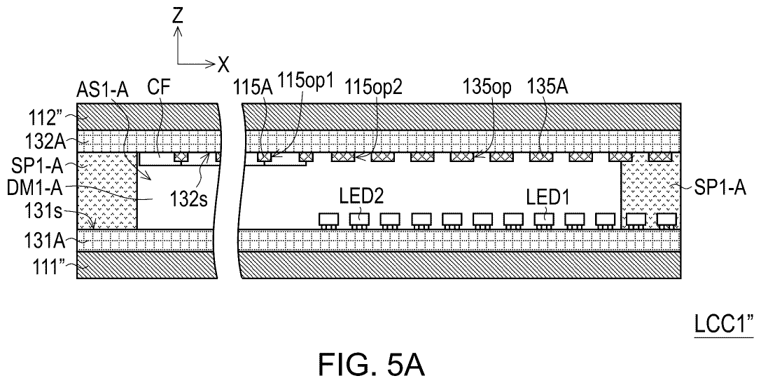

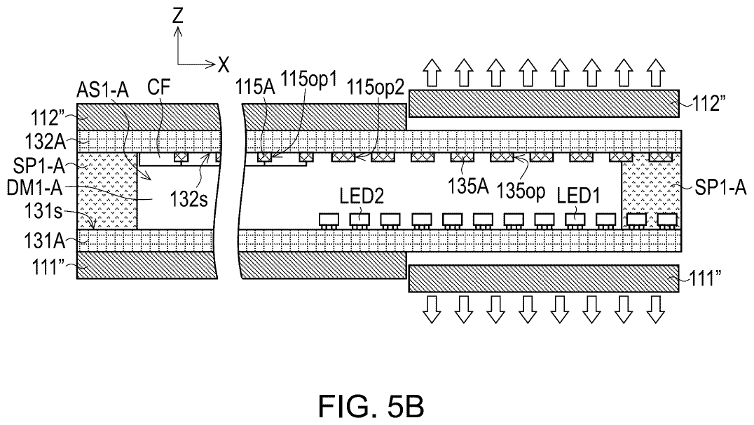

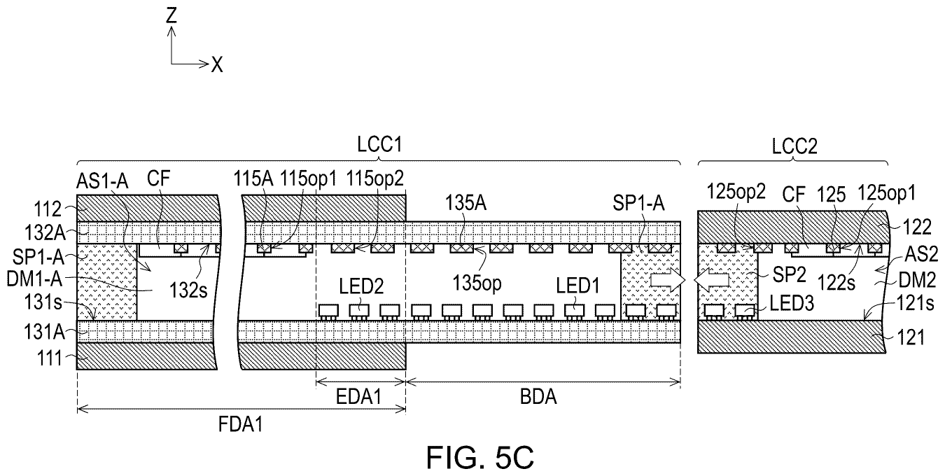

FIG. 4 is a schematic cross-sectional view of a display apparatus according to a second embodiment of the disclosure. FIGS. 5A to 5C are schematic cross-sectional views illustrating a manufacturing process of the display apparatus of FIG. 4. Referring to FIG. 4, the difference between a display apparatus 10A of the embodiment and the display apparatus 10 of FIG. 3 lies in that the structural configuration of the display apparatus in the first planar display area FDA1 is different.

It is first noted that, in the embodiment, the display apparatus 10A is formed by splicing a first display panel 110A and a second display panel 120. The first display panel 110A not only defines the first planar display area FDA1 of the display apparatus 10A, but also defines the bendable display area BDA.

Specifically, in the display apparatus 10A of the embodiment, the flexible substrate 131A and the flexible substrate 132A extend from the bendable display area BDA into the first planar display area FDA1. The display medium layer DM1-A extends into the edge display area EDA1 and the bendable display area BDA and covers the plurality of light-emitting elements LED1 and the plurality of light-emitting elements LED2. It should be particularly noted that the portion of the flexible substrate 131A located in the first planar display area FDA1 is disposed between the substrate 111 and the sealant pattern SP1-A, and the portion of the flexible substrate 132A located in the first planar display area FDA1 is disposed between the substrate 112 and the sealant pattern SP1-A. More specifically, the sealant pattern SP1-A is disposed between the flexible substrate 131A and the flexible substrate 132A. The plurality of light-emitting elements LED2 located in the edge display area EDA1 are electrically bonded to the surface 131s of the flexible substrate 131A, and the light-shielding layer 115A located in the first planar display area FDA1 is formed on the surface 132s of the flexible substrate 132A.

Unlike the foregoing embodiment in which the plurality of pixel structures and the plurality of signal lines for driving the display medium layer DM of FIG. 3 are formed on the substrate 111, in the embodiment, the plurality of pixel structures (not shown) and the plurality of signal lines (not shown) for driving the display medium layer DM1-A are formed on the flexible substrate 131A.

On the other hand, in the embodiment, the sealant pattern SP1-A of the first display panel 110A may extend from the first planar display area FDA1 to a side of the bendable display area BDA away from the first planar display area FDA1 and be adjacent to the sealant pattern SP2 of the second display panel 120. That is, there is no optical adhesive layer 137 as shown in FIG. 3 between the sealant pattern SP1-A and the sealant pattern SP2, and the display medium layer DM1-A and the display medium layer DM2 are separated by the sealant pattern SP1-A and the sealant pattern SP2. In the embodiment, the flexible substrate 131A, the flexible substrate 132A, and the sealant pattern SP1-A surrounding the first planar display area FDA1 and the bendable display area BDA define an accommodation space AS1-A for filling the display medium layer DM1-A.

The manufacturing process of the display apparatus 10A will be exemplarily described below.

First, a first liquid crystal cell LCC1″ as shown in FIG. 5A and a second liquid crystal cell LCC2 as shown in FIG. 5C are respectively fabricated. Referring to FIG. 5A, for example, a manufacturing method of the first liquid crystal cell LCC1″ may include: forming a flexible substrate 131A on a substrate 111″, electrically bonding a plurality of light-emitting elements LED1 and a plurality of light-emitting elements LED2 to the flexible substrate 131A, forming a flexible substrate 132A on a substrate 112″, forming a light-shielding layer 115A, a light-shielding layer 135A, and the color filter layer CF on the flexible substrate 132A, assembling the substrate 111″ and the substrate 112″ to define an accommodation space AS1-A between the flexible substrate 131A and the flexible substrate 132A, and filling the display medium layer DM1-A in the accommodation space AS1-A. In the embodiment, the light-shielding layer 115A and the light-shielding layer 135A may be of a same film layer, that is, the light-shielding layer 115A and the light-shielding layer 135A may be formed in the same process, but the disclosure is not limited thereto.

Next, removing a portion of the substrate 111″ overlapping the plurality of light-emitting elements LED1 and a portion of the substrate 112″ overlapping the plurality of light-emitting elements LED1 to a portion of each of the flexible substrate 131A and the flexible substrate 132A that overlap the plurality of light-emitting elements LED1, as shown in FIG. 5B. Since the flexible substrate 131A and the flexible substrate 132A have flexibility, after removing the portion of the substrate 111″ and the substrate 112″, the exposed portions of the flexible substrate 131A and the flexible substrate 132A may define the bendable display area BDA of the first liquid crystal cell LCC1, as shown in FIG. 5C. The unremoved portions of the substrate 111″ and the substrate 112″ serve as the substrate 111 and the substrate 112, respectively, and define the first planar display area FDA1 of the first liquid crystal cell LCC1.

Referring to FIG. 5C, for example, a manufacturing method of the second liquid crystal cell LCC2 may include: electrically bonding a plurality of light-emitting elements LED3 to the substrate 121, forming a light-shielding layer 125 and a color filter layer CF on the substrate 122, assembling the substrate 121 and the substrate 122 to define an accommodation space AS2 therebetween, and filling the display medium layer DM2 in the accommodation space AS2. After the fabrication of the first liquid crystal cell LCC1 and the second liquid crystal cell LCC2 is completed, the first liquid crystal cell LCC1 and the second liquid crystal cell LCC2 are spliced. Referring to FIGS. 4 and 5C, a backlight module BLU is then disposed on a side of the substrate 111 facing away from the display medium layer DM1-A, and a hinge structure 190 is disposed on the exposed flexible substrate 131A to form the first display panel 110A. Another backlight module BLU is disposed on a side of the substrate 121 facing away from the display medium layer DM2 to form the second display panel 120. Accordingly, the fabrication of the display apparatus 10A of FIG. 4 is completed.

It should be particularly noted that, in any direction (e.g., direction X) parallel to the surface 131s of the flexible substrate 131A, the surface 131s of the flexible substrate 131A may be aligned with the surface 121s of the substrate 121.

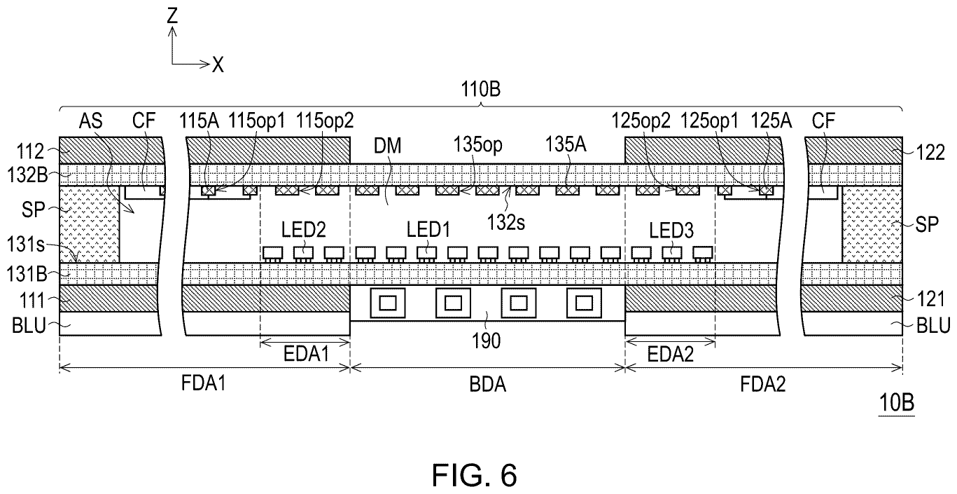

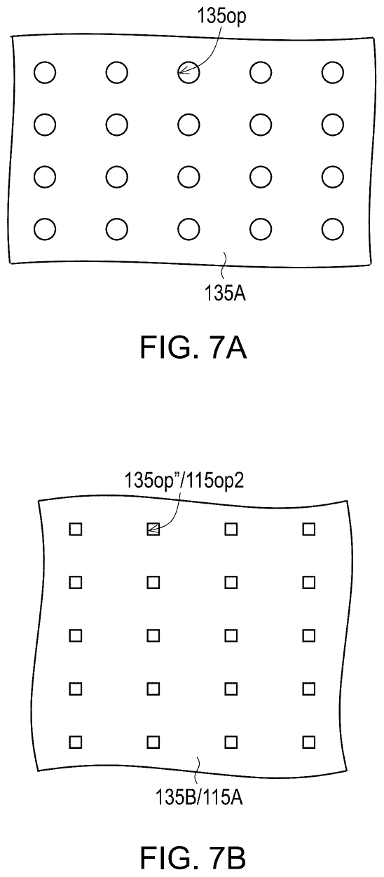

FIG. 6 is a schematic cross-sectional view of a display apparatus according to a third embodiment of the disclosure. FIG. 7A is a schematic top view of a light-shielding layer of FIG. 6. FIG. 7B is a schematic top view of another embodiment of the light-shielding layer of FIG. 6. Referring to FIG. 6, the difference between a display apparatus 10B of the embodiment and the display apparatus 10A of FIG. 4 lies in that the structural configuration of the display apparatus in the second planar display area FDA2 is different.

It is first noted that, in the embodiment, the display apparatus 10B is not formed by splicing at least two display panels, such as the display apparatus 10 of FIG. 3 or the display apparatus 10A of FIG. 4, but is constituted by a single display panel. For example, in the embodiment, the first planar display area FDA1, the second planar display area FDA2, and the bendable display area BDA of the display apparatus 10B are all defined by a first display panel 110B.

In detail, compared with the flexible substrate 131A, the flexible substrate 132A, and the display medium layer DM1-A of FIG. 4, the flexible substrate 131B, the flexible substrate 132B, and the display medium layer DM of the first display panel 110B of the embodiment may further extend into the second planar display area FDA2. It should be particularly noted that the portion of the flexible substrate 131B located in the second planar display area FDA2 is disposed between the substrate 121 and the sealant pattern SP, and the portion of the flexible substrate 132B located in the second planar display area FDA2 is disposed between the substrate 122 and the sealant pattern SP. Therefore, in the embodiment, the plurality of light-emitting elements LED3 located in the edge display area EDA2 are electrically bonded to the flexible substrate 131B, and the display medium layer DM further covers the light-emitting elements LED3. The light-shielding layer 115A located in the first planar display area FDA1, the light-shielding layer 125A located in the second planar display area FDA2, and the light-shielding layer 135A located in the bendable display area BDA may be of a same film layer formed on the flexible substrate 132B, but the disclosure is not limited thereto.

On the other hand, in the embodiment, the sealant pattern SP of the first display panel 110B may extend from a side of the first planar display area FDA1 away from the bendable display area BDA to a side of the second planar display area FDA2 away from the bendable display area BDA. The flexible substrate 131B, the flexible substrate 132B, and the sealant pattern SP surrounding the first planar display area FDA1, the bendable display area BDA, and the second planar display area FDA2 define an accommodation space AS for filling the display medium layer DM.

Since the manufacturing method of the first display panel 110B of the embodiment is similar to that of the first display panel 110A of FIG. 4, detailed descriptions may be found in the relevant paragraphs of the foregoing embodiments and will not be repeated herein.

Referring to FIGS. 6 and 7A, in the embodiment, an orthographic projection profile of each of the plurality of openings 135op of the light-shielding layer 135A located in the bendable display area BDA on the flexible substrate 132B may be circular, but the disclosure is not limited thereto. In another embodiment, the orthographic projection profile of each of the plurality of openings 135op″ of the light-shielding layer 135B on the flexible substrate 132B may be square (as shown in FIG. 7B). Notably, the design of the opening profile of the light-shielding layer may be adjusted according to the actually required light distribution pattern in the bendable display area BDA, and the disclosure is not limited thereto.

On the other hand, in the embodiment, to adjust the light output uniformity or light distribution pattern between the edge display area EDA1 of the first planar display area FDA1 and the bendable display area BDA, the orthographic projection profile of each of the plurality of openings 115op2 of the light-shielding layer 115A on the flexible substrate 132B (e.g., square as shown in FIG. 7B) may be different from the orthographic projection profile of each of the plurality of openings 135op of the light-shielding layer 135A on the flexible substrate 132B (e.g., circular as shown in FIG. 7A). Similarly, to adjust the light output uniformity or light distribution pattern between the edge display area EDA2 of the second planar display area FDA2 and the bendable display area BDA, the orthographic projection profile of each of the plurality of openings 125op2 of the light-shielding layer 125A on the flexible substrate 132B may also be different from the orthographic projection profile of each of the plurality of openings 135op of the light-shielding layer 135A on the flexible substrate 132B.

In summary, in a display apparatus according to an embodiment of the disclosure, a plurality of light-emitting elements are adapted to perform display in the bendable display area to improve image continuity between the planar display area and the bendable display area. In addition, since these light-emitting elements are disposed between two flexible substrates, protection for the light-emitting elements can be significantly enhanced.

What is claimed is:

1. A display apparatus, provided with a first planar display area and a bendable display area, comprising:
a first substrate and a second substrate, disposed in the first planar display area and opposite to each other;
a first display medium layer, disposed between the first substrate and the second substrate and located in the first planar display area;
a first flexible substrate and a second flexible substrate, disposed in the bendable display area and opposite to each other; and
a plurality of first light-emitting elements, disposed between the first flexible substrate and the second flexible substrate and located in the bendable display area.

2. The display apparatus according to claim 1, further comprising:
a plurality of second light-emitting elements, disposed between the first substrate and the second substrate, wherein the first planar display area includes a first edge display area connected to the bendable display area, the plurality of second light-emitting elements are located in the first edge display area, the plurality of first light-emitting elements are arranged on the first flexible substrate along a direction at intervals of a first pitch, the plurality of second light-emitting elements are arranged on the first substrate along the direction at intervals of a second pitch, and the first pitch is equal to the second pitch.

3. The display apparatus according to claim 2, further comprising:
a first light-shielding layer, disposed on the second flexible substrate; and
a second light-shielding layer, disposed on the second substrate, wherein an aperture ratio of the first light-shielding layer in the bendable display area is different from an aperture ratio of the second light-shielding layer in the first edge display area.

4. The display apparatus according to claim 3, wherein the first light-shielding layer has a plurality of first openings located in the bendable display area, the plurality of first openings are provided corresponding to the plurality of first light-emitting elements, the second light-shielding layer has a plurality of second openings located in the first edge display area, the plurality of second openings are provided corresponding to the plurality of second light-emitting elements, and an orthographic projection profile of each of the plurality of first openings on the second flexible substrate is different from an orthographic projection profile of each of the plurality of second openings on the second substrate.

5. The display apparatus according to claim 3, wherein the first light-shielding layer has a plurality of first openings located in the bendable display area, the second light-shielding layer has a plurality of second openings located in the first edge display area, the plurality of first openings are arranged along the direction at intervals of a third pitch, the plurality of second openings are arranged along the direction at intervals of a fourth pitch, and the third pitch is not equal to the fourth pitch.

6. The display apparatus according to claim 3, wherein the second flexible substrate extends to the first planar display area and is located between the second substrate and the second light-shielding layer, and the first light-shielding layer and the second light-shielding layer are of a same film layer.

7. The display apparatus according to claim 2, further comprising:
an optical adhesive layer, disposed between the first flexible substrate and the second flexible substrate and covering the plurality of first light-emitting elements; and
a first sealant pattern, disposed between the first substrate and the second substrate and covering the plurality of second light-emitting elements, wherein the first substrate, the second substrate, and the first sealant pattern define a first accommodation space, and the first display medium layer fills the first accommodation space.

8. The display apparatus according to claim 7, wherein the plurality of first light-emitting elements are electrically bonded to a first surface of the first flexible substrate, the plurality of second light-emitting elements are electrically bonded to a second surface of the first substrate, and the first surface of the first flexible substrate is aligned with the second surface of the first substrate along the direction.

9. The display apparatus according to claim 8, further provided with a second planar display area, and further comprising:
a third substrate and a fourth substrate, disposed in the second planar display area and opposite to each other;
a second display medium layer, disposed between the third substrate and the fourth substrate and located in the second planar display area; and
a second sealant pattern, disposed between the third substrate and the fourth substrate, wherein the bendable display area connects the first planar display area and the second planar display area, the third substrate, the fourth substrate, and the second sealant pattern define a second accommodation space, and the second display medium layer fills the second accommodation space.

10. The display apparatus according to claim 9, further comprising:
a plurality of third light-emitting elements, disposed between the third substrate and the fourth substrate, wherein the second planar display area includes a second edge display area connected to the bendable display area, the plurality of third light-emitting elements are located in the second edge display area, the plurality of third light-emitting elements are arranged on the third substrate along the direction at intervals of a third pitch, and the third pitch is equal to the first pitch.

11. The display apparatus according to claim 10, wherein the plurality of third light-emitting elements are electrically bonded to a third surface of the third substrate, and the third surface of the third substrate is aligned with the first surface of the first flexible substrate along the direction.

12. The display apparatus according to claim 10, wherein the second sealant pattern covers the plurality of third light-emitting elements, and the optical adhesive layer connects the first sealant pattern and the second sealant pattern.

13. The display apparatus according to claim 1, further comprising:
a hinge structure, disposed in the bendable display area and located on a side of the first flexible substrate facing away from the plurality of first light-emitting elements.

14. A display apparatus, provided with a first planar display area and a bendable display area, comprising:
a first substrate and a second substrate, disposed in the first planar display area and opposite to each other;
a first display medium layer, disposed between the first substrate and the second substrate and located in the first planar display area;
a first flexible substrate and a second flexible substrate, disposed in the bendable display area and opposite to each other;
a plurality of first light-emitting elements, disposed between the first flexible substrate and the second flexible substrate and located in the bendable display area; and
a plurality of second light-emitting elements, disposed between the first substrate and the second substrate, wherein the first planar display area includes a first edge display area connected to the bendable display area, the plurality of second light-emitting elements are located in the first edge display area, the plurality of first light-emitting elements are arranged on the first flexible substrate along a direction at intervals of a first pitch, the plurality of second light-emitting elements are arranged on the first substrate along the direction at intervals of a second pitch, the first pitch is equal to the second pitch, the first flexible substrate and the second flexible substrate extend into the first planar display area, and the first display medium layer extends into the first edge display area and the bendable display area and covers the plurality of first light-emitting elements and the plurality of second light-emitting elements.

15. The display apparatus according to claim 14, further provided with a second planar display area, and further comprising:
a third substrate and a fourth substrate, disposed in the second planar display area, wherein the bendable display area connects the first planar display area and the second planar display area, and the first flexible substrate, the second flexible substrate, and the first display medium layer further extend into the second planar display area; and
a sealant pattern, disposed between the first flexible substrate and the second flexible substrate, wherein the first flexible substrate, the second flexible substrate, and the sealant pattern define an accommodation space, and the first display medium layer fills the accommodation space.

16. The display apparatus according to claim 15, further comprising:
a plurality of third light-emitting elements, disposed between the third substrate and the fourth substrate, wherein the second planar display area includes a second edge display area connected to the bendable display area, the plurality of third light-emitting elements are located in the second edge display area, the plurality of third light-emitting elements are arranged on the first flexible substrate along the direction at intervals of a third pitch, and the third pitch is equal to the first pitch.

17. The display apparatus according to claim 16, wherein the plurality of first light-emitting elements, the plurality of second light-emitting elements, and the plurality of third light-emitting elements are electrically bonded to the first flexible substrate.

18. The display apparatus according to claim 14, further provided with a second planar display area, and further comprising:
a third substrate and a fourth substrate, disposed in the second planar display area and opposite to each other, wherein the bendable display area connects the first planar display area and the second planar display area;
a second display medium layer, disposed between the third substrate and the fourth substrate and located in the second planar display area; and
a first sealant pattern, disposed between the first flexible substrate and the second flexible substrate and located between the first display medium layer and the second display medium layer, wherein the first flexible substrate, the second flexible substrate, and the first sealant pattern define a first accommodation space, and the first display medium layer fills the first accommodation space.

19. The display apparatus according to claim 18, further comprising:
a plurality of third light-emitting elements, disposed between the third substrate and the fourth substrate, wherein the second planar display area includes a second edge display area connected to the bendable display area, the plurality of third light-emitting elements are located in the second edge display area, the plurality of third light-emitting elements are arranged on the third substrate along the direction at intervals of a third pitch, and the third pitch is equal to the first pitch; and
a second sealant pattern, disposed in the second edge display area and covering the plurality of third light-emitting elements, wherein the third substrate, the fourth substrate, and the second sealant pattern define a second accommodation space, and the second display medium layer fills the second accommodation space.

20. The display apparatus according to claim 19, wherein the plurality of first light-emitting elements and the plurality of second light-emitting elements are electrically bonded to a first surface of the first flexible substrate, the plurality of third light-emitting elements are electrically bonded to a second surface of the third substrate, and the first surface of the first flexible substrate is aligned with the second surface of the third substrate.
